(19) United States
(12) Patent Application Publication
(10) Pub. No.: US 2018/0254265 A1
(43) Pub. Date: Sep. 6, 2018

(54) MICRO- OR NANO-WIRE LED LIGHT SOURCE COMPRISING TEMPERATURE MEASUREMENT MEANS

(71) Applicant: VALEO VISION, Bobigny Cedex (FR)

(72) Inventors: Lothar SEIF, Bobigny Cedex (FR); Zdravko ZOJCESKI, Bobigny Cedex (FR)

(73) Assignee: VALEO VISION, Bobigny Cedex (FR)

(21) Appl. No.: 15/759,391

(22) PCT Filed: Sep. 13, 2016
(86) PCT No.: PCT/EP2016/071497

§ 371 Date: Mar. 12, 2018

(30) Foreign Application Priority Data
Sep. 14, 2015 (FR) 1558537

(51) Int. Cl. H01L 25/16; H01L 27/15; H01L 33/24; H01L 33/32; H01L 23/00; H01L 23/34; G01K 7/01

(52) U.S. Cl. CPC H01L 25/167; H01L 27/156; H01L 33/24; H01L 33/32; H01L 24/32; H01L 23/34; H01L 24/29; H01L 2224/29111; H01L 2224/29144; H01L 2924/12041; H01L 2924/014; H01L 2224/32145; H01L 2924/1203; G01K 7/01

(57) ABSTRACT

An electroluminescent light source including light-emitting rods of submillimetric size projecting from a substrate and distributed into a plurality of identical groups. The light source integrates means for measuring the temperature of the light-emitting rods. By using the provisions of the invention, it becomes possible to obtain accurate and local measurements of the temperature of the rods.

The invention relates to the field of lighting and light signaling, in particular for motor vehicles.

In the field of lighting and light signaling for motor vehicles, it is becoming increasingly common to use light sources based on light-emitting semiconductor components, for example light-emitting diodes, LEDs. An LED component emits light rays when a voltage with a value that is at least equal to a threshold value, referred to as direct voltage, is applied to its terminals.

In a known manner, one or more LEDs of a lighting module for a motor vehicle are supplied with power via power supply control means, which comprise converter circuits. The power supply control means are configured to convert an electric current of a first magnitude, for example delivered by a current source of the motor vehicle, such as a battery, into a load current having a second magnitude that is different from the first.

The operation of an LED depends on the temperature of its p-n junction. Beyond a threshold temperature, there is a risk of permanently damaging the LED component. The color of the light emitted by an LED and the intensity thereof also depends on the junction temperature. In general, the junction temperature depends on the magnitude of the electric current passing through it and on the ambient temperature of the lighting module. In order to be able to manage the desired light emission, and to be able to guarantee the longevity of LED components, it is known to use temperature measurement means that give an indication of the temperature of one or more LEDs. This information is then used by a circuit for controlling the supply of power to the LED. For LEDs in the form of chips implanted on a printed circuit board (PCB), use is made of surface-mounted device (SMD) temperature means, such as thermistors, the resistance of which depends on their temperature. By measuring the voltage drop across the terminals of the thermistor, it is possible to deduce the temperature of the thermistor. When the thermistor is positioned in the proximity of an LED on a PCB, it is possible to conclude that the measured temperature is an approximation of the junction temperature of the LED in question. The actual temperature of the junction is not able to be measured using this method. Above all in the field of lighting modules for motor vehicles, which imposes space restrictions on the electronic components, use is generally made of a limited number of thermistors even if a plurality of LEDs are present on a PCB, due to a lack of space. The quality of the approximation of the temperature of the individual LEDs obviously suffers as a result.

One aim of the invention is to propose a solution that overcomes the abovementioned problem. More particularly, one aim of the invention is to propose a micro-wire or nano-wire LED light source having integrated temperature measurement means.

One subject of the invention is an electroluminescent light source, comprising a first substrate and a plurality of light-emitting rods of submillimetric size projecting from the substrate. The light source is noteworthy in that it comprises means for measuring the temperature of the light-emitting rods.

The rods may preferably be arranged in a matrix. The matrix may preferably be regular, such that there is a constant spacing between two successive rods of a given alignment, or such that the rods are arranged in quincunx.

The height of a rod may preferably be between 1 and 10 micrometers.

The largest dimension of the end face may preferably be smaller than 2 micrometers.

The minimum distance separating two immediately adjacent rods may preferably be equal to 10 micrometers.

The area of the lighting surface of the light source may preferably be at most 8 mm².

The luminance achieved by the plurality of light-emitting rods may be for example at least 60 Cd/mm².

The temperature measurement means may preferably be means for directly measuring the temperature of the light-emitting rods.

The first substrate may preferably comprise silicon. The first substrate is advantageously made of silicon.

The temperature measurement means may preferably be arranged on a second substrate, the second substrate being attached to the first substrate on the face opposite the face from which the rods project.

The first and second substrates, the light-emitting rods and the measurement means may preferably be encapsulated in one and the same housing, in particular so as to form a single component.

The second substrate preferably comprises silicon. The second substrate is advantageously made of silicon.

The two substrates may preferably be attached by way of a gold-tin solder.

The temperature measurement means may preferably be integrated into the first substrate.

The temperature measurement means may preferably be arranged among the rods.

The light-emitting rods may preferably be distributed into a plurality of groups, the rods of each group being able to emit a specific light, and in that the source comprises temperature measurement means for each of the groups.

The light source may preferably comprise control means that are able to control each group independently of the other groups and on the basis of the temperature measurement of this group.

Each of the groups may preferably be able to emit a light of a specific intensity. Each of the groups may be able to emit a light of a specific color.

The temperature measurement means may preferably comprise a bipolar diode.

The temperature measurement means may preferably comprise an electronic circuit that bases its operation on the measurement of a variation in the direct voltage of a bipolar diode under the influence of a specific electric current, comprising an arrangement of transistors and/or a current generator. This electronic circuit may preferably be implanted directly into the substrate of the light source. The circuit may preferably be supplied with power jointly with the source, so that no additional connection to a dedicated current source is required.

The temperature measurement means may preferably comprise a group of light-emitting rods of the source.

Said group from among the rods may preferably be supplied with power periodically by said specific current for a duration shorter than the period and for the rest of the period by a given current so that the group contributes to a lighting function.

The temperature measurement means may preferably comprise an electronic measurement circuit. The measurement circuit may advantageously be integrated into the first substrate of the source.

Another subject of the invention is a lighting module comprising at least one light source able to emit light rays, and an optical device able to receive the light rays and to produce a light beam. The module is noteworthy in that the light source(s) are in accordance with the invention.

The provisions of the invention are beneficial in that they make it possible to obtain a measurement representative of the temperature of an electroluminescent nano-wire or micro-wire light source, which wires are also described as light-emitting rods. As the temperature means are implanted directly on the substrate of the light source or attached thereto, the measured temperature gives a good indication of the effective temperature of the semiconductor junctions of the rods. According to one preferred embodiment, a plurality of temperature measurement means may be implanted at specific positions on the substrate of the light source, thereby enabling robust management of the source and/or of various groups of rods of the source.

Other features and advantages of the present invention will be better understood with the aid of the description and the drawings, in which:

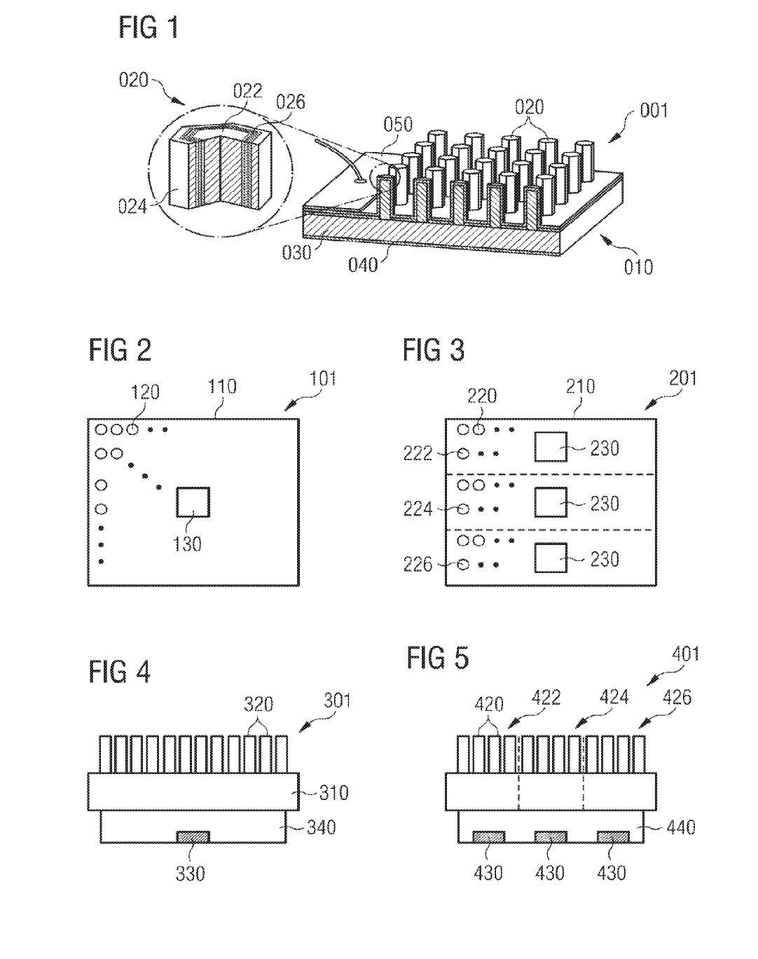

FIG. 1 is a depiction of a light source as implemented in one preferred embodiment of the present invention;

FIG. 2 is a schematic depiction of a view from above of a light source according to one preferred embodiment of the invention;

FIG. 3 is a schematic depiction of a view from above of a light source according to one preferred embodiment of the invention;

FIG. 4 is a schematic depiction of a lateral section of a light source according to one preferred embodiment of the invention;

FIG. 5 is a schematic depiction of a lateral section of a light source according to one preferred embodiment of the invention.

In the following description, similar reference numerals will generally be used to describe similar concepts across the various embodiments of the invention. Thus, the numerals 001, 101, 201, 301, 401 describe a light source of the various embodiments according to the invention.

Unless specified otherwise, technical features that are described in detail for one given embodiment may be combined with the technical features that are described in the context of other embodiments described by way of non-limiting example.

FIG. 1 illustrates an electroluminescent light source 001 according to a first embodiment of the invention. FIG. 1 illustrates the basic principle of the light source. The light source 001 comprises a substrate 010 on which are arranged a series of light-emitting diodes in the form of wires or rods 020 projecting from the substrate. The core 022 of each rod 020 is made of n-type semiconductor material, that is to say doped with electrons, while the envelope 024 is made of p-type semiconductor material, that is to say doped with holes. A recombination zone 026 is provided between the n-type and p-type semiconductor materials. It is however possible to contemplate reversing the semiconductor materials, in particular depending on the chosen technology.

The substrate is advantageously made of silicon, and the rods have a diameter of less than one micron. As a variant, the substrate comprises a layer of semiconductor material doped with holes, and the wires have a diameter of between 100 and 500 nm. The semiconductor material doped with electrons and with holes forming the diodes may advantageously be gallium nitride (GaN) or gallium-indium nitride (InGaN). The height of a rod is typically between 1 and 10 micrometers, whereas the largest dimension of the end face is smaller than 2 micrometers. According to one preferred embodiment, the rods are arranged in a matrix in a regular arrangement. The distance between two rods is constant and equal to at least 10 micrometers. The rods may be arranged in quincunx. The area of the lighting surface of such a light source is at most 8 mm². The source is capable of producing a luminance of at least 60 Cd/mm².

With reference to FIG. 1, the substrate 010 comprises a main layer 030, advantageously made of silicon, a first electrode or cathode 040 arranged on the face of the main layer that is opposite the rods 020, and a second electrode or anode 050 arranged on the face comprising the diodes 020. The anode 050 is in contact with the p-type semiconductor material forming the envelopes 024 of the diodes 020 and extending on the corresponding face of the substrate 010, so as to form a conductive layer between said envelopes 024 and the anode 050. The cores or centers 022 of the rods are, for their part, in contact with the main semiconductor layer 030 and also in electrical contact with the cathode 040.

When an electric voltage is applied between the anode and the cathode, electrons of the n-type semiconductor material recombine with holes of the p-type semiconductor material and emit photons. The majority of the recombinations are radiative. The emitting face of the diodes is the p zone, as this is the most radiative.

According to some embodiments of the invention, the light source 001 comprises a plurality of groups of light-emitting rods linked to different anodes. Each group is thus able to be supplied with electric power independently of the other(s). The diodes or rods of each group are advantageously all of the same type, that is to say emitting in the same spectrum and emitting at a common intensity. The groups are advantageously identical and exhibit a common direct voltage. Each group therefore preferably comprises substantially the same number of semiconductor wires. According to the principle of the invention, temperature measurement means are integrated into the source 001.

Such an integration is shown in preferred and exemplary embodiments by FIGS. 2 to 5. FIG. 2 shows an electroluminescent light source 101 comprising a substrate 110 and a plurality of light-emitting rods 120 in the form of wires projecting from the substrate. The source furthermore comprises means 130 for measuring the temperature of the rods. The substrate 110 is advantageously made of silicon, thereby making it possible to integrate the temperature measurement means 130 directly into the substrate 110. Directly implanting the measurement means 130 into the middle of the diodes 120 makes it possible to obtain a measurement point that is physically very close to the semiconductor junctions whose temperature it is desired to measure. This integration into the light source makes it possible to limit the space required to arrange the temperature measurement means, in comparison with known solutions. The measurement means may preferably comprise a bipolar diode. Advantageously, such an electronic circuit, which bases its operation on the measurement of a variation in the direct voltage of a bipolar diode under the influence of a specific electric current, comprising an arrangement of transistors and/or a current generator, is able to be implanted directly into the substrate 110 of the light source. The circuit is supplied with power jointly with the source 101, so that no additional connection to a dedicated current source is required. As an alternative to using a dedicated bipolar diode, one group from among the rods 120 of the light source 110 may be used to obtain a measurement of the temperature. In this case, the group in question is supplied with power by said specific electric current. Advantageously, said group from among the rods 120 is supplied with power periodically by said specific current for a duration shorter than the period and for the rest of the period by a given current so that the group contributes to a lighting function.

The embodiment of FIG. 3 takes up the features of FIG. 2. The electroluminescent light source 201 comprising a substrate 210 and a plurality of light-emitting rods 220 projecting from the substrate. In this embodiment, the rods 220 are distributed into three separate groups 222, 224, 226. Obviously, a larger number of groups may be provided for a given light source and depending on the intended application. Although the groups are shown in the form of strips, their geometry may be arbitrary. Each group comprises light-emitting rods 220 having similar features and is able to be supplied with power independently, such that each group emits a light having a specific intensity and/or color. The source furthermore comprises means 230 for measuring the temperature of the diodes for each of the groups 222, 224, 226. The substrate 210 is advantageously made of silicon, thereby making it possible to integrate the temperature measurement means 230 directly into the substrate 210.

In the embodiment of FIG. 4, the electroluminescent light source 301 comprises a first substrate 310 and a plurality of light-emitting rods 320 projecting from the substrate. In this embodiment, means for measuring the temperature of the rods are implanted on a second substrate 340 attached to the first substrate 310, so as to guarantee a good thermal link between the two substrates. The two substrates are attached to one another, for example by way of a gold-tin solder. The second substrate 340 is attached to the first substrate 310 on that face of the latter that is opposite the face on which the diodes 320 project. The location of the temperature measurement means 330 is chosen so as to obtain a measurement representative of the temperature of the rods 320. The component resulting from this assembly is of ‘multi chip package’ type, the second substrate integrating an additional function, that is to say the temperature measurement, with respect to the primary function of the source, i.e. the emission of light rays.

The embodiment of FIG. 5 takes up the features of FIG. 3. The electroluminescent light source 401 comprising a substrate 410 and a plurality of light-emitting rods 420 projecting from the substrate. In this embodiment, the rods 420 are distributed into three separate groups 422, 424, 426. A larger number of groups may be provided for a given light source and depending on the intended application, without otherwise departing from the scope of the present invention. Although the groups are shown in the form of strips, their geometry may be arbitrary. Each group comprises rods 420 having similar features and is able to be supplied with power independently, such that each group emits a light having a specific intensity and/or color. The source furthermore comprises means 430 for measuring the temperature of the rods for each of the groups 422, 424, 426. The measurement means 430 may be implanted on a second substrate 440 common to all of the measurement means. As an alternative, it is possible to provide one dedicated substrate per means 430. The substrate(s) 430 are attached to the first substrate in a manner similar to the embodiment of FIG. 4 described above. The location of the means 430 is chosen so as to be able to measure, for each of the groups of rods 422, 424, 426, a temperature representative of the rods in question.

1. A semiconductor light source, comprising:
a first substrate;
a plurality of light-emitting rods of submillimetric size projecting from the substrate; wherein
the source comprises means for measuring the temperature of the light-emitting rods.

2. The light source as claimed in claim 1, wherein the first substrate comprises silicon.

3. The light source as claimed in claim 1, wherein the temperature measurement means are arranged on a second substrate, the second substrate being attached to the first substrate on the face opposite the face from which the rods project.

4. The light source as claimed in claim 3, wherein the second substrate comprises silicon.

5. The light source as claimed in claim 3, wherein the two substrates are attached by way of a gold-tin solder.

6. The light source as claimed in claim 2, wherein the temperature measurement means are integrated into the first substrate.

7. The light source as claimed in claim 6, wherein the temperature measurement means are arranged among the rods.

8. The light source as claimed in claim 1, wherein the rods are distributed into a plurality of groups, the rods of each group being able to emit a specific light, and wherein the source comprises temperature measurement means for each of the groups.

9. The light source as claimed in claim 8, wherein each of the groups are able to emit a light of a specific intensity and/or color.

10. The light source as claimed in claim 1, wherein the temperature measurement means comprise a bipolar diode.

11. The light source as claimed in claim 1, wherein the temperature measurement means comprise a group of light-emitting rods of the source.

12. The light source as claimed in claim 1, wherein the temperature measurement means comprise an electronic measurement circuit.

13. The light source as claimed in claim 12, wherein the measurement circuit is integrated into the first substrate of the source.

14. A lighting module comprising:
at least one light source able to emit light rays;
an optical device able to receive the light rays and to produce a light beam;
wherein the light source(s) are as claimed in claim 1.

15. The light source as claimed in claim 2, wherein the temperature measurement means are arranged on a second substrate, the second substrate being attached to the first substrate on the face opposite the face from which the rods project.

16. The light source as claimed in claim 4, wherein the two substrates are attached by way of a gold-tin solder.

17. The light source as claimed in claim 2, wherein the rods are distributed into a plurality of groups, the rods of each group being able to emit a specific light, and wherein the source comprises temperature measurement means for each of the groups.

18. The light source as claimed in claim 2, wherein the temperature measurement means comprise a bipolar diode.

19. The light source as claimed in claim 2, wherein the temperature measurement means comprise a group of light-emitting rods of the source.

20. The light source as claimed in claim 2, wherein the temperature measurement means comprise an electronic measurement circuit.
